(19) United States
(12) Patent Application Publication
(10) Pub. No.: US 2023/0343546 A1
(43) Pub. Date: Oct. 26, 2023

(54) DEVICE AND METHOD FOR PREPARING MICROSCOPIC SAMPLES

(71) Applicant: Carl Zeiss Microscopy GmbH, Jena (DE)

(72) Inventors: Michele Nicoletti, Muenchen (DE); Josef Biberger, Wildenberg (DE)

(21) Appl. No.: 18/304,266

(22) Filed: Apr. 20, 2023

Related U.S. Application Data
(62) Division of application No. 16/459,212, filed on Jul. 1, 2019, now abandoned.

(30) Foreign Application Priority Data
Jul. 26, 2018 (DE) 102018212511.2

(51) Int. Cl. H01J 37/20; H01J 37/28

(52) U.S. Cl. CPC H01J 37/20; H01J 37/28; H01J 2237/20214; H01J 2237/31749; H01J 2237/2802; H01J 2237/31745

(57) ABSTRACT

The disclosure relates to a receptacle device for receiving and preparing a microscopic sample. The receptacle device is mountable onto a sample stage. The sample stage is arranged in a sample chamber of a microscope system and is movable by way of an open kinematic chain of rotational or rotational and translational elements. The last rotational element of the open kinematic chain is arranged such that it is rotatable about an axis R₁. The receptacle device has an axis R₂, about which the receptacle device is arranged such that it is rotatable. The axis R₂ is arranged at an angle α relative to the axis R₁. The angle α assumes a value in the range of 10° to 80°. By rotation of the receptacle device about the axis R₂, the receptacle device can adopt at least a first position and a second position.

### CROSS-REFERENCE TO RELATED APPLICATION

This application is a divisional of, and claims priority to U.S. application Ser. No. 16/459,212, filed Jul. 1, 2019, which claims priority under 35 U.S.C. § 119 to German Application No. 10 2018 212 511.2, filed Jul. 26, 2018. The contents of this application are hereby incorporated by reference in its entirety.

### FIELD

The disclosure relates to devices and methods for preparing microscopic samples, such as TEM lamellae, for example, which are intended to be examined in a microscope.

### BACKGROUND

Normally a microscope system is used to produce a microscopic sample. In the case of microscope systems which operate with a beam of charged particles, such as, for example, electron microscopes, ion beam microscopes, two- or multi-beam apparatuses, the microscopic sample to be prepared is usually held on a movable sample stage.

A two-beam apparatus is a combination apparatus including both an electron beam column and an ion beam column (focused ion beam, FIB). Two-beam apparatuses are often used to observe samples with the aid of the electron beam column and to process these with the aid of the ion beam column. By way of example, a cross section can be produced or a TEM lamella can be prepared in a two-beam apparatus.

For the preparation and/or observation of the microscopic sample, the sample—depending on the process step—is held in different positions, that is to say spatial locations and spatial orientations, relative to the optical axes of the particle beam columns. Often the sample is rotated and/or to tilted.

The movements of the sample can be realized using a five-axis stage, so that the sample can be moved in a targeted manner in the spatial directions X and Y, and also in the spatial direction Z, such that the distance between the sample and the objective lens of the particle beam apparatus can also be varied. Moreover, a five-axis stage has two rotation axes, wherein a first rotation axis usually extends parallel to the Z-axis, while a further rotation axis (tilt axis) is oriented orthogonally to the first rotation axis. A five-axis stage is generally configured such that eucentric tilting of the sample is possible.

A five-axis stage usually includes translational and rotational movement elements arranged successively in an open kinematic chain.

However, the possibilities for movement of a sample held on a sample stage are generally limited. Owing to the geometric conditions, the possibility for movement of the second rotation axis (tilt axis), in particular, is insufficient for certain preparation and examination methods.

Therefore, further degrees of freedom of movement may be desired—depending on the embodiment of the microscope system used.

In order to make these degrees of freedom available, an additional stage (so-called substage) can be mounted onto the sample stage. It is also conceivable to use a micromanipulator that provides an additional degree of freedom of movement.

It is known that a sample stage can include an additional stage and a rotation unit, such that the sample can be rotated about an axis, wherein the additional rotation axis is oriented perpendicularly to the Z-axis of the stage.

Moreover, various attachment devices have been described which can be mounted onto a sample stage in order to enable an additional rotational movement of the sample.

Furthermore, methods are known in which a micromanipulator has a rotation axis, such that a sample secured to the micromanipulator can be moved by rotation about this axis. Examples of references are DE 102007026847 (Schertel & Zeile), U.S. Pat. No. 7,474,419 B2 (Tappel et al.), and U.S. Pat. No. 8,642,958 B2 (Takahashi et al.)

### SUMMARY

The present disclosure proposes a receptacle device for samples and a sample holder system with which an additional degree of freedom of movement is provided for a received sample.

Moreover, the present disclosure proposes methods which facilitate the sample preparation since the receptacle device according to the disclosure makes available an additional degree of freedom of movement.

In an aspect, the disclosure provides a receptacle device for receiving and preparing a microscopic sample. The receptacle device is mountable onto a sample stage. The sample stage is arranged in a sample chamber of a microscope system and is movable by way of an open kinematic chain of rotational or rotational and translational elements. The last rotational element of the open kinematic chain is arranged such that it is rotatable about an axis R₁. The receptacle device has an axis R₂, about which the receptacle device is arranged such that it is rotatable. The axis R₂ is arranged at an angle α relative to the axis R₁, and the angle α assumes a value in the range of 10° to 80°. The receptacle device can adopt at least a first position and a second position. The receptacle device is transferrable from one position into another position by rotation about the axis R₂.

In an aspect, the disclosure provides a sample holder system for preparing a microscopic sample. The sample holder system includes a receptacle device for receiving a sample block from which a microscopic sample is intended to be extracted. The sample holder also includes a receptacle device for receiving an extracted sample as disclosed herein.

In an aspect, the disclosure provides a method for preparing a microscopic sample with the aid of a multi-beam apparatus which includes an electron beam column for generating an electron beam and an ion beam column for generating a focused ion beam. The electron beam column and the ion beam column each have an optical axis. The method includes providing a first receptacle device for receiving a microscopic sample. The first receptacle device is mountable onto a sample stage of the multi-beam apparatus, and the sample stage is arranged in a sample chamber of the multi-beam apparatus and is movable by way of an open kinematic chain of rotational or rotational and translational elements. The last rotational element of the open kinematic chain is arranged such that it is rotatable about an axis R₁. The first receptacle device has an axis R₂, about which the first receptacle device is arranged such that it is rotatable. The axis R₂ is arranged at an angle α relative to the axis R₁ and the angle α assumes a value in the range of 10° to 80°. The receptacle device can adopt at least a first position and a second position, which are different from one another. The receptacle device is transferrable from one position into another position by rotation about the axis R₂. The method also includes receiving a microscopic sample into the first receptacle device, and holding the first receptacle device in the first position, such that the sample is held in a first spatial orientation relative to the optical axes of the multi-beam apparatus. The method further includes imaging the surface to be processed of the microscopic sample with the aid of the electron beam. In addition, the method includes rotating the first receptacle device about the axis R₂ until the first receptacle device adopts the second position, such that the microscopic sample adopts a second spatial orientation relative to the optical axes of the multi-beam apparatus. The second spatial orientation is different from the first spatial orientation. Further, the method includes processing the microscopic sample using the focused ion beam.

In an aspect, the disclosure provides a method for preparing a microscopic sample via back side thinning, with the aid of a multi-beam apparatus and a receptacle device. The multi-beam apparatus includes an electron beam column for generating an electron beam and an ion beam column for generating a focused ion beam. The electron beam column and the ion beam column each have an optical axis. The receptacle device is mountable onto a sample stage of the multi-beam apparatus. The sample stage is arranged in a sample chamber of the multi-beam apparatus and is movable by way of an open kinematic chain of rotational or rotational and translational elements. The last rotational element of the open kinematic chain is arranged such that it is rotatable about an axis R₁. The receptacle device has an axis R₂, about which receptacle device is arranged such that it is rotatable. The axis R₂ is arranged at an angle α relative to the axis R₁ and the angle α assumes a value in the range of 10° to 80°. The receptacle device can adopt at least a first position and a second position, which are different from one another. The receptacle device is transferrable from one position into another position by rotation about the axis R₂. The method includes providing a microscopic sample that has already been thinned by processing using the ion beam, such that the sample has a side that faced the ion beam during the this first processing phase. The method also includes first rotating of the sample about a rotation axis, such that the sample adopts a first spatial orientation relative to the optical axes of the multi-beam apparatus, and transferring the sample to the receptacle device. The method further includes second rotating of the sample relative to the optical axes by the receptacle device being rotated about the axis R₂, such that the sample adopts a second spatial orientation relative to the optical axes so that the side of the sample that faced the ion beam during the first processing phase now faces away from the ion beam. In addition, the method includes processing the sample using the ion beam.

In an aspect, the disclosure provides a computer program which includes a sequence of control commands that causes a microscope system to carry out a method as disclosed herein.

The disclosure is based on the insight that it is particularly advantageous if the sample to be prepared is held in a receptacle device that is arranged such that it is rotatable about a rotation axis R₂. In this case, the receptacle device is arranged on a movable sample stage, and the rotation axis R₂ is oriented at an angle of approximately 45° relative to the rotation axis R₁ of the sample stage. It is also conceivable for the angle between the two rotation axes mentioned to adopt a different value between 0° and 90°, in particular between 10° and 80°. At all events an additional degree of freedom of movement is made available, such that the sample can be rotated by 90° in space, without further aids such as e.g. a micromanipulator having to be used.

Exemplary embodiments of the disclosure are described below with reference to figures. Therefore, in order to explain the components, reference is also made to the respectively preceding and subsequent description in its entirety.

### BRIEF DESCRIPTION OF THE DRAWINGS

FIGS. 1A and 1B schematically show an advantageous configuration of the receptacle device according to the disclosure, in first and second positions, respectively.

FIGS. 2A and 2B schematically show examples of a first and a second spatial orientation, respectively, of a sample held by a receptacle device according to the disclosure.

FIG. 3A shows a first sample holder system according to the disclosure in plan view, and FIG. 3B shows a second sample holder system according to the disclosure in plan view.

FIG. 4 shows a flowchart of a method for preparing microscopic samples with the aid of a receptacle device according to the disclosure.

FIG. 5 shows a flowchart of a method for so-called back side thinning.

FIGS. 6A-6I illustrate, in a schematic cross-sectional view, the different spatial orientations adopted by a sample if it is prepared in accordance with the method shown in FIG. 5.

FIGS. 7A-7D show a flowchart of an in-situ preparation method according to the disclosure with subsequent STEM examination.

FIG. 8 schematically shows one embodiment of a microscope system including a receptacle device according to the disclosure.

FIG. 9 shows the schematic illustration of a further embodiment of a microscope system including a receptacle device according to the disclosure.

FIG. 10 shows a flowchart of a method for preparing a horizontal TEM lamella (plane view lamella).

### DESCRIPTION OF EXEMPLARY EMBODIMENTS

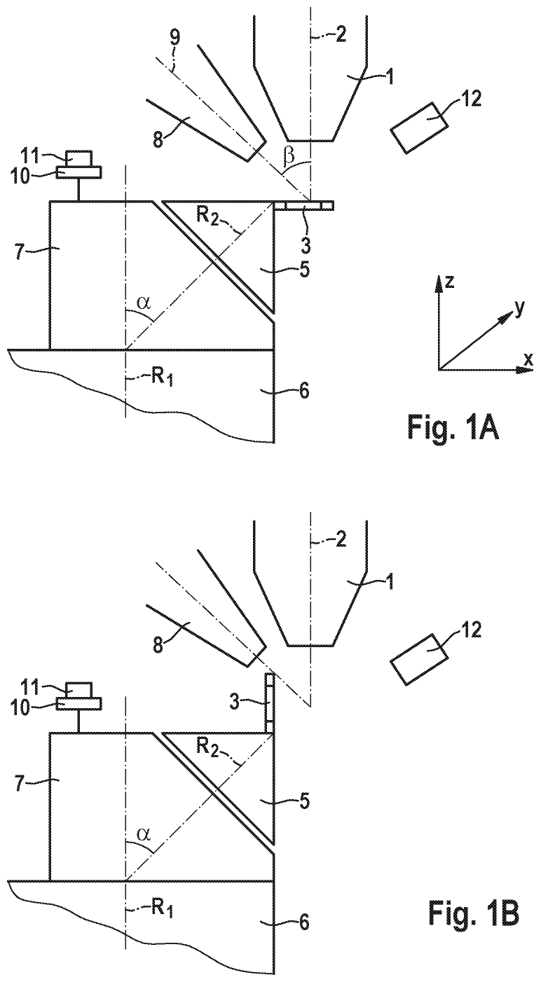

FIGS. 1A and 1B schematically show one advantageous configuration of the receptacle device 5 according to the disclosure in cross-sectional view. A microscopic sample 3 is held via a receptacle device 5. The receptacle device 5 is situated in a sample chamber (not depicted) of a microscope system. The microscope system can be a particle beam apparatus that operates with a beam of charged particles, such as a scanning electron microscope (SEM), an ion beam microscope or a multi-beam apparatus, for example. The sample 3 can be for example the precursor of a TEM lamella that has previously been extracted from a sample block and transferred into the receptacle device 5.

An image of the sample 3 can be generated with the aid of an electron beam column 1 and a suitable detector 12. The electron beam column 1 has an optical axis 2. Moreover, the sample 3 can be processed with the aid of an ion beam generated in an ion beam column 8. The ion beam column 8 has an optical axis 9 oriented at an angle β, which can be 54°, for example, relative to the optical axis 2 of the electron beam column.

The receptacle device 5 is included by a sample holder 7, which is in turn mounted on a movable sample stage 6. Alternatively, it is also conceivable for the receptacle device to be mounted directly on the sample stage. The movable sample stage 6 has at least one rotation axis R₁, about which the sample stage 6 is arranged such that it is rotatable.

It is particularly advantageous if the sample stage 6 has a plurality of translational and rotational degrees of freedom of movement. This is the case, for example, if the sample stage 6 is embodied as a five-axis stage including the translational axes X, Y and Z and the rotation axes R₁ and T (tilt axis). In this case, the translation axes mentioned are oriented in each case perpendicularly to one another. The rotation axes are generally likewise oriented perpendicularly to one another.

A sample to be examined can thus be moved in the three spatial directions X, Y and Z by a five-axis stage in order to change the spatial location of the sample. The spatial location is understood to mean the positioning of the sample in three-dimensional space. The exact spatial location of the sample can be described by the indication of X-, Y- and Z-coordinates.

Moreover, the spatial orientation, i.e. the orientation of the sample relative to the optical axis/axes of the microscope system, can be altered by the sample being rotated and/or tilted via the rotation axes. In this case, it is particularly advantageous if the sample stage is embodied as a eucentric sample stage. That means that a sample which is held by the sample stage and which is arranged at the eucentric point can be tilted, without its moving laterally in the process. It is also conceivable for the sample stage to be embodied as a six-axis stage, that is to say as a five-axis stage (so-called super-eucentric stage) having an additional axis, the so-called M-axis.

In general, the movement of the sample stage is realized by translational (Z, M, X, Y) and rotational movement elements (T, R) being arranged successively in an open kinematic chain, such that the movement elements can be moved and/or oriented relative to one another. The axes can be arranged for example in the order Z-T-M-X-Y-R or Z-T-X-Y-M-R, wherein the sample to be examined is connected in each case to the last element of the chain. This is also referred to as stacking of the movement axes (axis stacking).

The arrangement in an open kinematic chain means that a movement element carries out in each case not only the movement realized by it, but also passively the movements of those other movement elements which are arranged upstream of the movement element in the chain. That is to say, therefore, that the movement of the first movement element in the chain, for example Z, concomitantly moves all other axes disposed downstream (in this example: in the Z-direction).

On the other hand, a movement element arranged last in the open kinematic chain has no further controllable degrees of freedom of movement. That is to say, therefore, that the last movement element can actively carry out only the movement assigned to it.

In the case of the embodiment shown in FIG. 1, the rotational movement element responsible for the rotation of the sample stage 6 about the axis R₁ is arranged as the last rotational movement element in an open kinematic chain.

In order to open up a further possibility for moving the sample 3, the receptacle device 5 has a rotation axis R₂, about which the receptacle device 5 is arranged such that it is rotatable. This is particularly advantageous in order to vary the spatial orientation of the sample. The axis R₂ is arranged at an angle α relative to the axis R₁. The angle α can assume a value of 0° to 90°. It is advantageous if the angle α assumes a value of approximately 10° to 80°, in particular 40° to 60° or 20° to 30°. It can be particularly advantageous if the angle α is substantially 45°.

Optionally, the sample holder 7 additionally includes a further receptacle device 10, onto which a sample block 11 can be received. A microscopic sample can be freely prepared and extracted from the sample block (bulk sample) 11. The freely prepared sample 3 can be transferred and received into the receptacle device 5, where it can then be subjected to further preparation steps such as thinning and polishing. The transfer of the extracted sample from the sample block 11 to the receptacle device 5 can be carried out in situ, that is to say without the sample needing to be removed from the sample chamber or the vacuum in the sample chamber needing to be breached.

FIG. 1A shows the receptacle device 5 in a first position. The first position can be chosen—as illustrated—for example such that the sample 3 can be imaged with the aid of the electron microscope functions of the microscope system. By rotation of the receptacle device about the axis R₂, the receptacle device is transferred into a second position, which is illustrated in FIG. 1B. The second position can be chosen for example such that the sample 3 in an altered spatial orientation can be observed via the SEM or can be processed using a focused ion beam generated in the ion beam column 8.

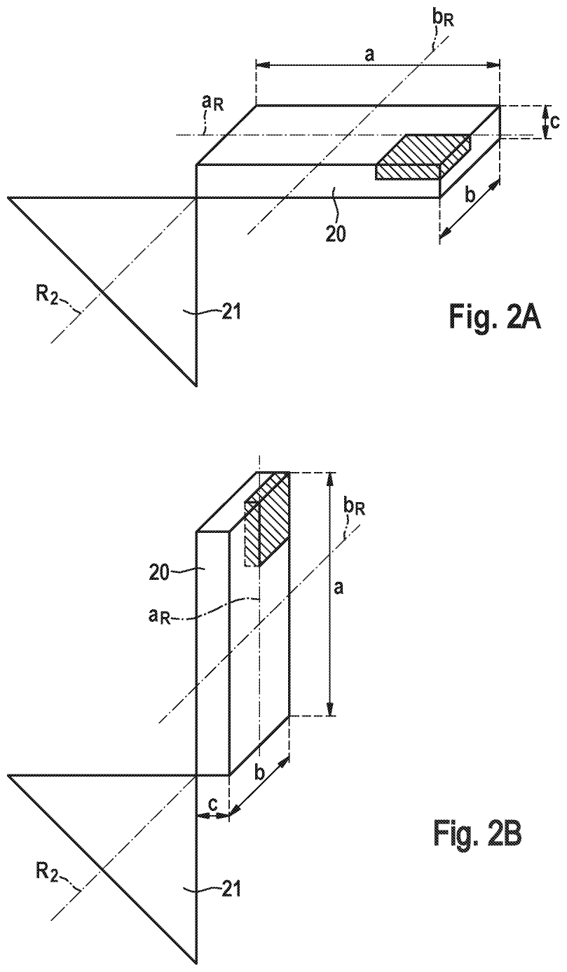

The sample can be a TEM lamella 20, for example, as illustrated in FIG. 2. A TEM lamella 20 usually has the shape of a flat parallelepiped which, at least in one region, is so thin that electrons can be radiated through it. Electrons that have penetrated through the TEM lamella 20 (i.e. transmitted electrons) can then be detected and used for image generation.

The parallelepipedal sample 20 has the edges a, b and c. Firstly, the receptacle device 21 is situated in a first position (FIG. 2A), wherein the side surface to be examined of the TEM lamella 20 is held in a first spatial orientation, for example perpendicular to the optical axis of the electron beam column.

As a result of the rotational movement about the axis R₂, the receptacle device 21 is moved into the second position (FIG. 2B), such that the TEM lamella 20 adopts a second spatial orientation, which is different from the first spatial orientation. In comparison with the first spatial orientation, the TEM lamella 20 is rotated by 90° about an axis b_{R} extending parallel to the edge b and is rotated by 180° about an axis a_{R} extending parallel to the edge a. The side surface to be examined of the TEM lamella 20 is now oriented parallel to the optical axis of the electron beam column.

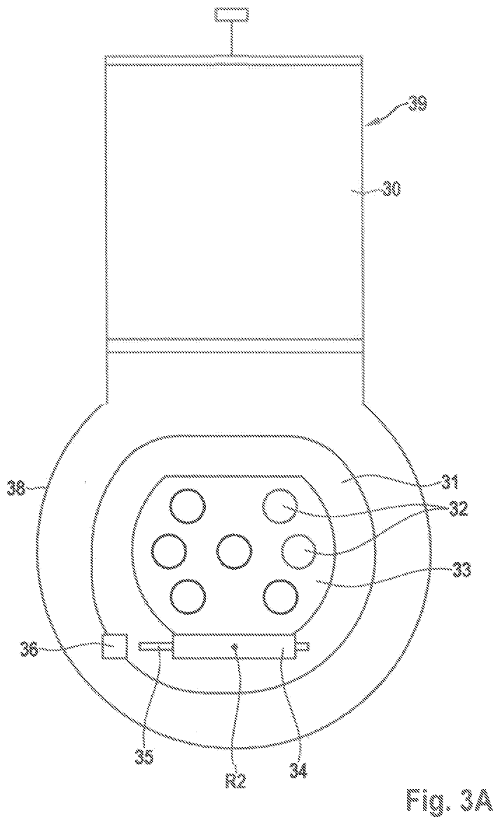

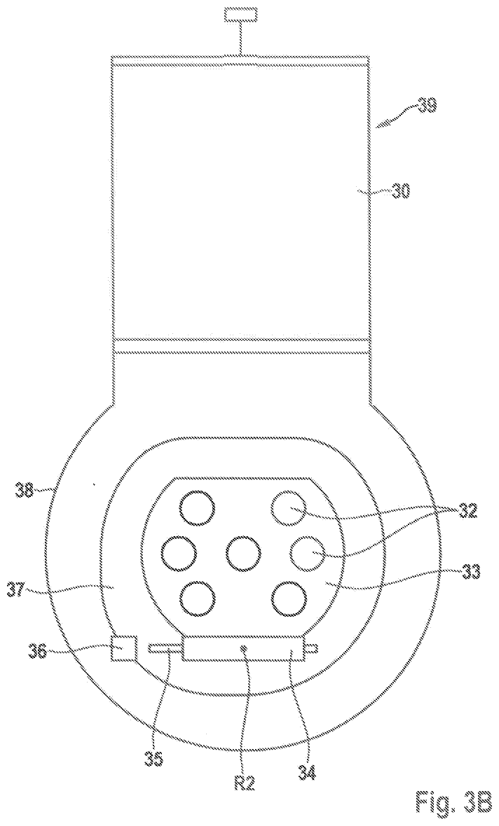

FIG. 3 shows a receptacle device 34 according to the disclosure and a sample holder system 33 according to the disclosure in plan view. The sample holder system 33 includes a first receptacle device 34 for receiving and preparing a microscopic sample, and at least one second receptacle device 32 for receiving a sample block from which the microscopic sample is extracted.

As shown in FIG. 3B, the sample holder system 33 is mounted onto a movable sample stage 37 and arranged in the sample chamber 31 of a microscope system. The sample chamber 31 is delimited by a chamber wall 38 and is embodied in such a way that vacuum conditions can be maintained in the sample chamber 31.

The receptacle device 34 includes an activatable switching element 35. By activation of the switching element 35, the rotational movement of the receptacle device 34 about the axis R2 (illustrated in plan view in FIG. 3B) can be initiated. As a result, the receptacle device 34 is moved from the first position into the second position, or from the second position into the first.

It is advantageous, moreover, if the first position is a position in which the sample is oriented such that, for example, the focused ion beam impinges on the sample more or less perpendicularly. The second position can be chosen such that the sample is held in a position such that the ion beam impinges on the sample with grazing incidence, such that thinning or polishing can be effected.

It is particularly advantageous, in addition, if the receptacle device is embodied in a eucentric fashion. For this purpose, the geometry of the receptacle device is chosen such that the upper edge of the receptacle device 34 substantially lies in the sample plane of the sample stage equipped with a eucentric tilting possibility. The receptacle device then likewise enables a eucentric tilting, that is to say that a received sample can be tilted eucentrically.

Moreover, the receptacle device should be embodied to be as flat as possible, i.e. with the smallest possible extent in the Z-direction. As a result, the receptacle device can be tilted through a large tilt angle. This has the advantage that, in a specific embodiment of a two-beam apparatus in which the angle β between the particle beam columns is 54° (cf. FIG. 1), the receptacle device can be tilted by more than 54°, for example by up to 64°, relative to the optical axes. This is particularly expedient for the processing using the ion beam.

In one advantageous configuration, the microscope system includes an activation element 36, by which the switching element 35 can be activated in order to initiate the rotational movement of the receptacle device 34. The activation element 36 can be arranged for example at a movement element of an upstream axis of the sample stage 37. However, as shown in FIG. 3A, it is also conceivable for the activation element 36 to be arranged at the chamber wall 38.

The activation can be realized by the switching element 35 and the activation element 36 being moved relative to one another. By way of example, the sample stage 37 together with the receptacle device 34 can be moved such that switching element 35 and activation element 36 touch one another or come into contact in some other way. This has the advantage that no drive device need be provided in the receptacle device itself.

However, it is also conceivable that the receptacle device can be rotated by way of one or more actuators. It is conceivable for electric or piezo drives to be used for this purpose, for example.

It is particularly advantageous if the sample holder system 33 is embodied such that it is transferrable via a lock 39 of the microscope system. The sample holder system 33 can be introduced into the sample chamber 31 of the microscope system from outside the microscope system via a lock chamber 30 of the lock 39. This is particularly advantageous if the microscope system is embodied as a particle beam apparatus in which a sample has to be examined and processed under vacuum conditions. As a result of the lockability of the sample holder system 33 according to the disclosure, when changing the sample it is not necessary to breach the vacuum in the sample chamber 31, with the result that changing the sample is significantly accelerated.

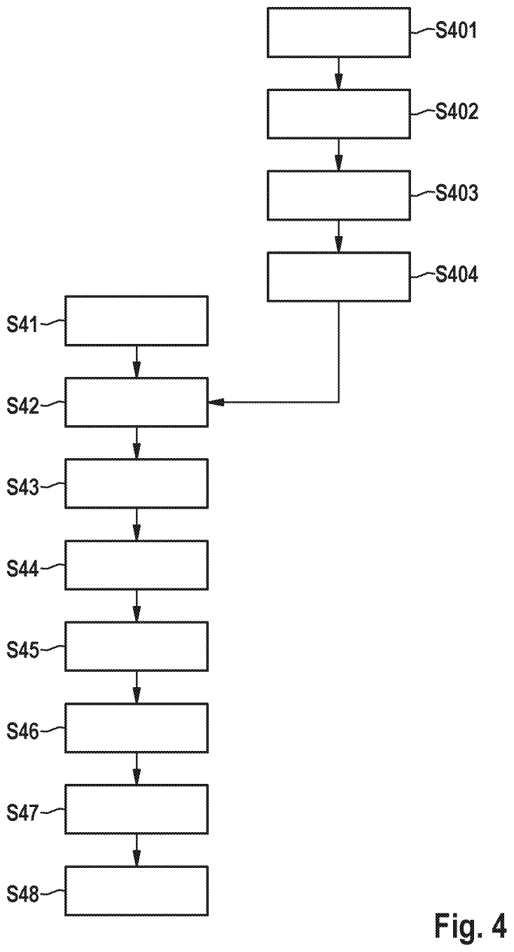

FIG. 4 shows the sequence of a method according to the disclosure for preparing a microscopic sample. A first step S41 involves providing a device according to the disclosure for receiving the sample (as described above). The receptacle device includes an axis R₂, about which the receptacle device is arranged such that it is rotatable. The receptacle device can be received on a movable sample stage having at least one rotation axis R₁, about which the sample stage is arranged such that it is rotatable. The rotation axis R₁ is arranged as the last rotational movement element in an open kinematic chain of movement elements.

The axes R₂ and R₁ form an angle α with respect to one another. The angle α can assume a value of 0° to 90°. It is advantageous if the angle α assumes a value of approximately 10° to 80°, in particular 40° to 60° or 20° to 30°. It is particularly advantageous if the angle α is substantially 45°.

The subsequent step involves receiving a sample to be processed into the receptacle device (step S42). The sample can be for example a vertical TEM lamella (cross section, cross-sectional lamella) or a horizontal TEM lamella (plane view, planar lamella). The receptacle device is situated in a sample chamber of a microscope system with which the microscopic sample is intended to be prepared. This can be for example an SEM-FIB combination apparatus including an electron beam column and an ion beam column, which each have an optical axis.

Firstly, the receptacle device is held in a first position (step S43). In this case, the sample adopts a first spatial orientation relative to the optical axes of the microscope system. It is particularly advantageous if the sample is oriented in space such that a particle beam generated in one of the particle beam columns of the combination apparatus impinges on the sample substantially perpendicularly.

Step S44 involves processing the sample using the ion beam. However, it is also conceivable for an image of the sample to be generated in step S44, for example by a particle beam being directed onto the sample and interacting with the sample material. The interaction products that arise, such as backscattered electrons or secondary electrons, for example, can then be detected with the aid of a detector and used for image generation.

In the next step S45, the receptacle device is rotated about the axis R₂. As a result, the sample is moved such that it adopts a second spatial orientation relative to the optical axes of the microscope system, the second spatial orientation being different from the first spatial orientation. The receptacle device remains in the second position, such that the sample is held in the second spatial orientation (step S46).

Optionally, in step S47, the orientation of the sample can be altered by the sample stage being moved. In this regard, by way of example, the sample can be oriented in space such that the ion beam of the two-beam apparatus impinges on the sample with grazing incidence in order to be able to process the side surfaces of the TEM lamella.

In step S48, an image of the sample is generated or the sample is processed, for example by thinning using a focused ion beam.

In one particular configuration of the preparation method, the sample to be processed, which is provided in step S42, is prepared and extracted in situ from a sample block (bulk sample). For this purpose, a sample holder system is provided which includes, besides the first receptacle device, a second receptacle device for receiving a sample block (original sample), as illustrated in FIG. 3.

For this purpose, in step S401, a sample block from which the sample is intended to be extracted is received into the second receptacle device.

A sample region including a region of interest (ROI) is then exposed for example using a focused ion beam (step S402). For this purpose, the sample region can be covered with a protective layer of platinum or carbon. The exposed sample region is secured to a micromanipulator tip. This can be done by welding with the aid of the ion beam. In step S403, the exposed sample region that is intended thereafter to be processed and examined as the sample is then separated and removed from the sample block (so-called lift-out).

In step S404, the extracted sample is finally transferred to the first receptacle device with the aid of a micromanipulator, such that the method can subsequently be carried out with steps S42 to S48.

One advantage in the case of this embodiment of the method is that both lift-out and the further preparation and examination of the sample can be carried out in situ, i.e. within the sample chamber of the microscope system.

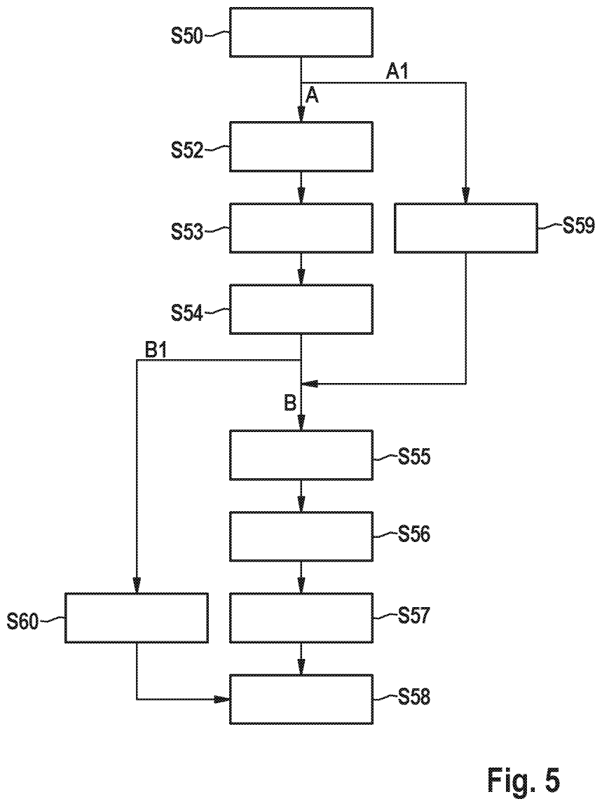

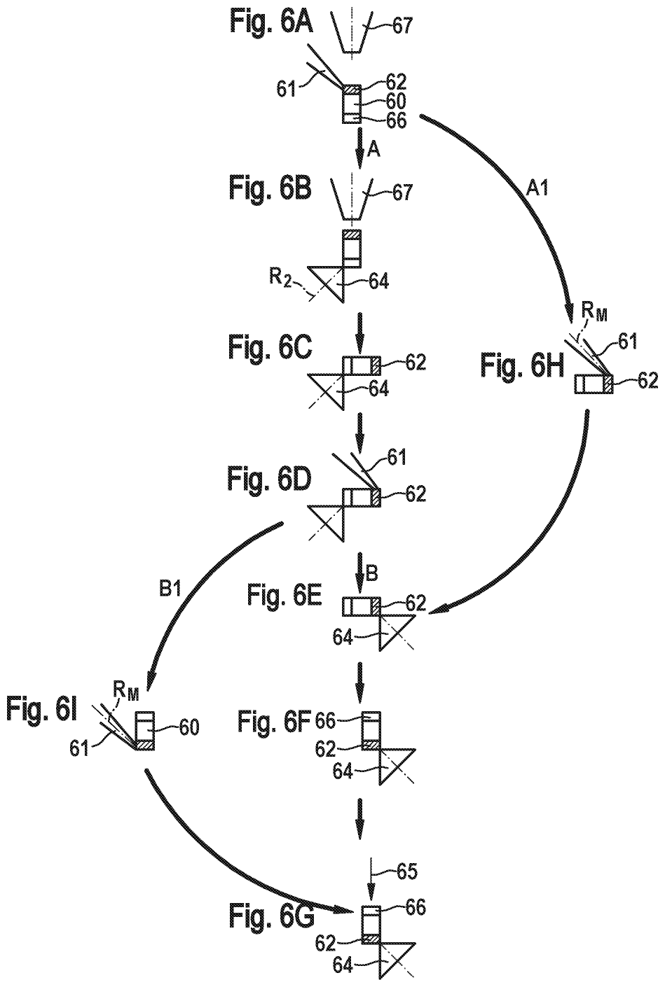

A further particular embodiment of the method according to the disclosure relates to so-called back side thinning, which is important for processing with grazing incidence of the particle beam. This embodiment is illustrated schematically in FIG. 5 and FIG. 6. In back side thinning, the direction of incidence of the beam of charged particles used for processing is inverted in the course of the method. Undesired curtaining effects can be reduced as a result.

FIG. 5 shows the schematic sequence of the method, which has two variation possibilities (alternatives A/A1 and alternatives B/B1). The alternatives A1 and B1 are implemented in each case with a micromanipulator having a rotatable shaft or having a rotatable tip. FIG. 6 shows, highly schematically and not to scale, the different spatial orientations adopted by the sample during the progress of the method illustrated as a workflow in FIG. 5.

Firstly, a sample 60 is prepared from a sample block with the aid of the focused ion beam and is thinned in a first processing phase. Usually, for this purpose, firstly a protective layer is applied to the sample surface in a targeted manner, such that the region of interest (ROI) is maintained in the sample. For thinning purposes, the sample is processed using an ion beam. In this case, the ion beam impinges on a first side 62 (front side) of the sample, facing the incident ion beam. The sample additionally has a second side 66 (back side), facing away from the ion beam. Undesired curtaining effects can occur in the region of the second side 66 (back side) of the sample.

After thinning, the sample is extracted from the sample block (lift-out). A micromanipulator is usually used for this purpose, the exposed sample being transferred to the needle tip of the micromanipulator. Step S50 thus involves providing a freely prepared, prethinned sample held by a micromanipulator tip 61. FIG. 6A shows the freely prepared sample 60 on the micromanipulator tip 61.

Then (step S52) the sample is transferred to a receptacle device according to the disclosure, which is situated in the sample chamber of a microscope system, for example an SEM-FIB combination apparatus. The receptacle device is included by a movable sample stage, which can be moved via rotational or translational and rotational movement elements. The movement elements of the sample stage are arranged serially one after another, such that they form an open kinematic chain. The rotation axis R₁ of the sample stage is the last rotational movement element in the open kinematic chain, such that the rotation axis R₁ has no further controllable degrees of freedom of movement.

The receptacle device has an axis R₂ arranged at the angle α relative to a rotation axis R₁ of the sample stage. In this case, it is particularly advantageous if the axes R₁ and R₂ form an angle α of substantially 45° with respect to one another (α=45°).

However, it is also conceivable for the angle α to adopt some other value between 0° and 90°.

As illustrated in FIG. 6B, the receptacle device 63 adopts a first position relative to the optical axis 67 of the microscope system, such that the sample 60 adopts a first spatial orientation relative to the optical axes of the microscope system. The sample is advantageously oriented in space such that a particle beam can impinge on the sample perpendicularly or with grazing incidence.

Then (step S53) the receptacle device is transferred into a second position by the receptacle device being rotated about the axis R₂. The sample 60 then adopts a second spatial orientation relative to the optical axis 67, the second spatial orientation being different from the first spatial orientation (FIG. 6C).

In the subsequent step (step S54)—as illustrated in FIG. 6D—the sample 60 is transferred to the tip 61 of the micromanipulator needle 61 and fixed. The sample can be secured to the tip for example by material being deposited via the ion beam.

In an alternative embodiment of the method (alternative A1), steps S52, S53 and S54 (identified as alternative A in FIG. 5) are omitted. Instead, the sample is left on the micromanipulator tip 61, wherein the micromanipulator has a rotation axis R_{M}, about which the sample can be rotated. It is conceivable for the rotation axis R_{M} to extend along the longitudinal axis of the shaft of the micromanipulator or for the micromanipulator to have a rotatable tip and for the rotation axis R_{M} to correspond to the longitudinal axis of the tip. In the alternative embodiment A1, step S59 involves rotating the micromanipulator about the axis R_{M}, such that as a result of this rotational movement the spatial orientation of the sample is changed in the same way as in step S53. The change in the spatial orientation of the sample is shown in FIG. 6H.

Independently of whether alternative A or A1 was implemented, step S55 involves providing a receptacle device according to the disclosure, which is situated in the first position.

Step S56 involves transferring the sample to the receptacle device 64 (FIG. 6E).

Finally, the receptacle device is transferred into the second position (step S57), such that the sample adopts a different spatial orientation relative to the optical axes 67 of the microscope system, as shown in FIG. 6F.

Finally, in step S58, the sample is processed using a particle beam, which can be a focused ion beam, for example. This is illustrated in FIG. 6G. The side 66 of the sample (back side) facing away from the ion beam during the first processing phase (before step S50) now lies on the side of the incident ion beam 65 and can be processed using the ion beam 65. The back side 66 of the sample thus becomes the front side—in each case as viewed from the direction of the incident particle beam. That means that the processing direction has been inverted in this second processing phase in relation to the first processing phase; the sample is now processed upside down. This has the advantage that curtaining effects from the first processing phase are reduced.

In a further alternative embodiment of the method (alternative B1), steps S55, S56 and S57 (identified as B in FIG. 5) are omitted. Instead, the sample is left on the micromanipulator tip after step S54. The micromanipulator shaft or the micromanipulator tip is rotated about the axis R_{M} (FIG. 6I), such that as a result of this rotational movement the spatial orientation of the sample is changed in the same way as in step S57.

Since attaching the sample to the micromanipulator tip constitutes a relatively important step, it is particularly advantageous if, in one specific method configuration, the alternatives A1 and B1 from FIG. 5 (corresponding to FIGS. 6A, 6H, 6E, 6F, 6G, 6I) are combined with one another. In this method sequence, the sample is transferred to the micromanipulator needle only once, namely during the lift-out from the sample block, which precedes step S50 of the method according to the disclosure. After the lift-out, the prethinned sample is firstly rotated about the rotation axis R_{M} (variant A1) and is then rotated, with the aid of the receptacle device according to the disclosure, about the rotation axis R₂, such that back side thinning can be carried out.

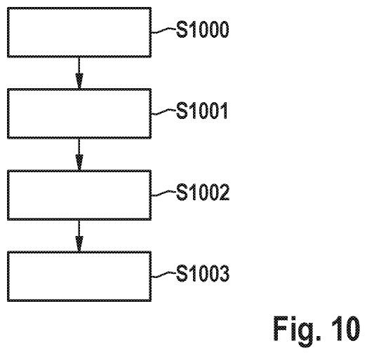

FIG. 10 shows a method according to the disclosure for preparing a plane view lamella, which method is similar to the method described in FIG. 5 (alternative A).

Step S1000 involves providing a freely prepared, wedge-shaped sample held by a micromanipulator tip. In order to produce a horizontal lamella, firstly a wedge-shaped sample piece is exposed from a sample block with the aid of the focused ion beam. In general, for this purpose, a protective layer is applied to the sample surface, such that the region of interest (ROI) in the sample is protected. The wedge-shaped sample is extracted from the sample block and transferred to a needle tip of a micromanipulator. The sample wedge can be secured to the needle tip e.g. via ion beam deposition.

Then (step S1001) the sample is transferred to a receptacle device according to the disclosure, which is arranged in a sample chamber of a microscope system. The receptacle device is situated on a movable sample stage, as described for FIG. 5. The receptacle device has an axis R₂ arranged at the angle α relative to a rotation axis R₁ of the sample stage, wherein the angle α can assume the values described for FIG. 5.

The receptacle device adopts a first position relative to the optical axes of the microscope system, such that the sample is held in a first spatial orientation relative to the optical axes of the microscope system. The sample is advantageously oriented in space such that a particle beam can impinge on the sample perpendicularly and the sample can be processed or observed.

Then (step S1002) the receptacle device is transferred into a second position by the receptacle device being rotated about the axis R₁. The sample then adopts a second spatial orientation relative to the optical axis. By way of example, in the second spatial orientation, the particle beam can impinge on the sample with grazing incidence. That can mean, for example, that the sample has been rotated by 90° in comparison with the first spatial orientation.

Step 1003 involves processing the sample using a particle beam, which can be a focused ion beam, for example, wherein the final lamella shape can be worked therefrom.

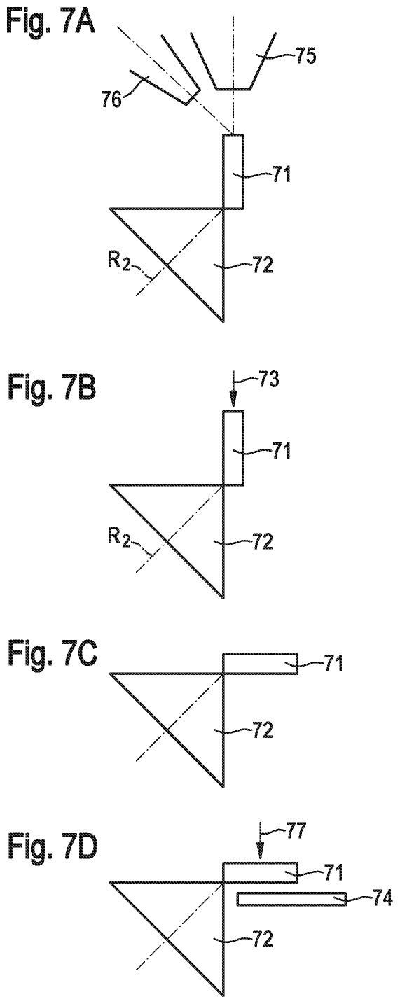

FIG. 7 shows a flowchart of an in-situ preparation method according to the disclosure with subsequent STEM examination. During the STEM (Scanning Transmission Electron Microscopy) examination, electrons are radiated through a sample that is transparent to electrons at least in places, and the transmitted electrons are subsequently detected.

Firstly, a TEM lamella 71 to be examined is received into a receptacle device 72 (FIG. 7A), which is connected to a sample stage. The microscope system advantageously includes an electron beam column 75 and an ion beam column 76. The receptacle device 72 and the sample stage (not illustrated) have the features mentioned in the description for FIG. 1.

The receptacle device is situated in a first position, in which the TEM lamella 71 is held such that it can be processed, for example thinned and polished (FIG. 7B), using an ion beam 73.

The receptacle device 72 is then rotated about the axis R₂ (FIG. 7C), such that the receptacle device 72 adopts a second position and the TEM lamella 71 is transferred into a second spatial orientation.

A STEM detector 74 can then be positioned below the TEM lamella in order to radiate an electron beam 77 through the TEM lamella in order to carry out STEM examinations (FIG. 7D).

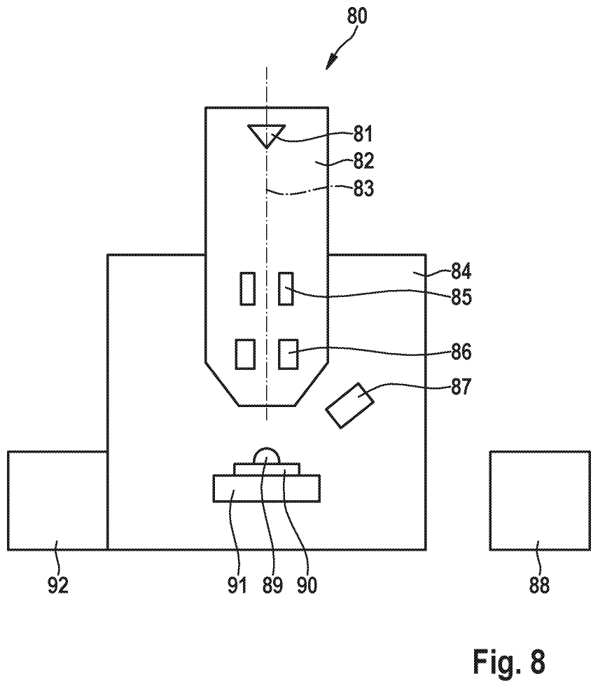

FIG. 8 shows an FIB system 80 as one example of a microscope system into which a receptacle device according to the disclosure can be received. With the aid of the FIB system, a focused ion beam (FIB) is generated and is directed onto a sample 89. The sample 89 to be prepared is held via a receptacle device 90 on a movable sample stage 91 and is situated in a sample chamber 84 of the particle beam apparatus. The FIB system includes an ion beam column 82 having an optical axis 83. The ion beam column 82 includes at least one deflection system 85 and a focusing lens 86.

During operation, ions are generated in an ion source 81, the ions being accelerated and focused along the optical axis 83 of the ion beam column 82, with the result that the ions impinge on the sample 89 in a focused manner. The particle beam apparatus includes at least one detector 87 for detecting interaction products of the interaction of ion beam and sample material, such that an image of the sample can be generated. Moreover, the sample 89 can be processed, e.g. thinned or polished, with the aid of the focused ion beam.

The microscope system advantageously includes a movable sample stage 91, onto which the receptacle device 90 can be received directly or indirectly. The sample stage 91 is advantageously embodied as a eucentric five-axis stage. That means that the sample can be moved in the X-, Y- and Z-directions—that is to say in three mutually perpendicular spatial directions—and can be rotated about a tilt axis and a rotation axis.

Vacuum conditions usually prevail in the sample chamber 84 during operation. Therefore, it is particularly advantageous if the microscope system has a lock device 92, via which the receptacle device 90 loaded with a sample 89 can be introduced and discharged, without the vacuum of the sample chamber needing to be breached in the process.

Moreover, the microscope system has a control device 88, into which can be loaded a computer program which has the effect that the microscope system carries out one of the methods described.

It is also conceivable for the microscope system to be embodied as a scanning electron microscope. In contrast to the FIB system described above, the scanning electron microscope has an electron beam column for generating an electron beam instead of an ion beam column.

During operation, primary electrons are generated in an electron source (cathode), the primary electrons being accelerated along the optical axis of the electron beam column, focused by condenser lens systems and trimmed by at least one aperture stop. Moreover, the electron beam column includes a deflection system, by which the primary electron beam is guided over the surface of the sample in a raster-type fashion. The scanning electron microscope includes at least one detector for detecting interaction products of the interaction of particle beam and sample.

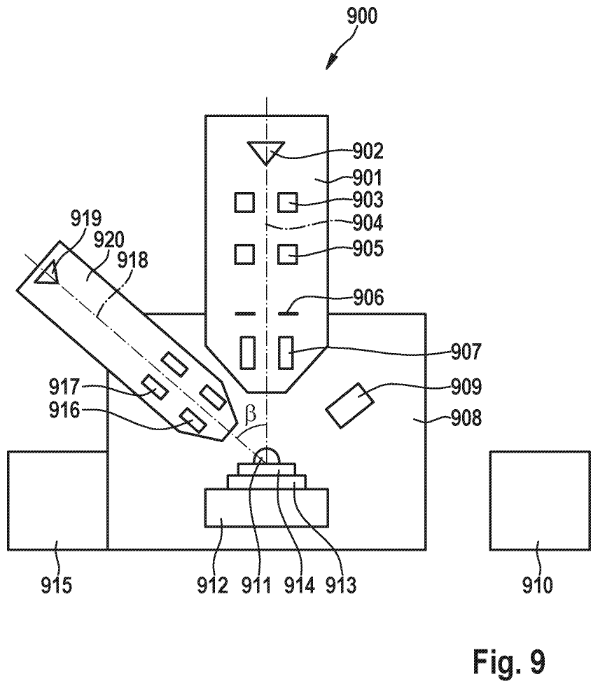

It is also conceivable for the microscope system—as illustrated in FIG. 9—to be embodied as a two-beam apparatus 900, that is to say as an FIB-SEM combination apparatus having both an ion beam column 920 and an electron beam column 901. The electron beam column 901 includes an electron source 902, a first condenser lens system 903, a second condenser lens system 905, an aperture stop 906 and a deflection system 907. The optical axis 904 of the electron beam column extends parallel to the principal axis of the electron beam column 901. Moreover, the two-beam apparatus 900 includes an ion beam column 920 having an optical axis 918. The ion beam column 920 includes an ion source 919, a focusing lens 916 and a deflection system 917, with the aid of which a focused ion beam can be directed over the sample 911.

The electron beam column 901 and the ion beam column 920 generally adopt a fixed angle β with respect to one another, which is usually between 20° and 60°, for example 54°. However, two-beam apparatuses are also known in which the two columns are arranged orthogonally with respect to one another, such that the angle β is 90°.

Both particle beams that can be generated via the two-beam apparatus are directed onto the processing site on the sample 911, which is usually situated at the coincidence point of both particle beams. The sample 911 to be examined is received into a receptacle device 914. The receptacle device 914 is received onto a movable sample stage 912 directly or by way of a sample holder system 113, the sample stage being situated in an evacuatable sample chamber 908. Moreover, the two-beam apparatus 900 has at least one detector 909 for detecting interaction products. Furthermore, the two-beam apparatus 900 has a control device 910. It is particularly advantageous if the two-beam apparatus 900 additionally includes a lock device 915 for introducing and discharging the receptacle device loaded with the sample, or the sample holder system.

What all the microscope systems described have in common is that they have a control device 88, 910. The control device 88, 910 can carry out a sequence of control commands encompassed in a computer program. As a result of the command sequence being carried out, the respective microscope system 80, 900 is caused to carry out one of the methods according to the disclosure for sample preparation.

The preparation method according to the disclosure is not restricted to the exemplary microscope systems shown. It is likewise conceivable to use the method according to the disclosure when observing and/or processing samples that are intended to be examined using light microscopes, laser microscopes or x-ray microscopes.

### LIST OF REFERENCE SIGNS

1 Electron beam column
2 Optical axis of the electron beam column
3 Microscopic sample
5 Receptacle device
6 Sample stage
7 Sample holder
8 Ion beam column
10 9 Optical axis of the ion beam column
10 Second receptacle device
11 Sample block
12 Detector
R₁ Rotation axis R₁ of the sample stage
R₂ Rotation axis R₂ of the receptacle device
α Angle between rotation axis R₁ and rotation axis R₂
β Angle between the optical axes of the particle beam columns
20 Sample (TEM lamella)
21 Receptacle
device
a Edge a
b Edge b
c Edge c
a_{R} First rotation axis, extending parallel to edge a
b_{R} Second rotation axis, extending parallel to edge b
30 Lock chamber
31 Sample chamber
32 Second receptacle device
33 Sample holder system
34 First receptacle device
35 Switching element
36 Activation element
37 Sample stage
38 Chamber wall
39 Lock
S41 Providing receptacle device
S42 Receiving TEM lamella
S43 Holding the receptacle device in first position
S44 Imaging/processing the TEM lamella
S45 Rotating the receptacle device about axis R₂
S46 Holding the receptacle device in second position
S47 Orienting the TEM lamella (optional)
S48 Processing/imaging the TEM lamella
S401 Receiving sample block into second receptacle device
S402 Exposing the sample using ion beam
S403 Extracting the sample (lift-out)
S404 Transferring the extracted sample to first receptacle device
S50 Providing freely prepared, prethinned sample on micromanipulator
S52 Transferring sample to receptacle device
S53 Transferring receptacle device into second position
S54 Transferring sample to micromanipulator
S55 Providing receptacle device in first position
S56 Transferring sample to receptacle device
S57 Transferring receptacle device into second position
S58 Processing sample using particle beam
S59 Alternative A1: Rotation about axis of the micromanipulator
S60 Alternative B1: Rotation about axis of the micromanipulator
60 Sample
61 Micromanipulator tip
62 First side of the sample (front side)
64 Receptacle device
5 65 Ion beam
66 Second side of the sample (back side)
67 Optical axis of the microscope system
R_{M} Rotation axis in micromanipulator
71 Sample (TEM lamella)
72 Receptacle device
73 Ion beam
74 STEM detector
75 Electron beam column
76 Ion beam column
77 Electron beam
80 FIB system
81 Ion source
82 Ion beam column
83 Optical axis of the ion beam column
84 Sample chamber
85 Deflection system
86 Focusing lens
87 Detector
88 Control device
89 Sample
90 Receptacle device
91 Sample stage
92 Lock device
900 Two-beam apparatus
901 Electron beam column
902 Electron source
903 First condenser lens system
904 Optical axis of the electron beam column
905 Second condenser lens system
906 Aperture stop
907 Deflection system
908 Sample chamber
909 Detector
910 Control device
911 Sample
912 Sample stage
913 Sample holder
914 Receptacle device
915 Lock device
916 Focusing lens
917 Deflection system
918 Optical axis of the ion beam column
919 Ion source
920 Ion beam column
S1000 Providing sample
S1001 Transferring sample to receptacle device
S1002 Transferring receptacle device into second position
S1003 Processing sample

1.-20. (canceled)

21. A method of moving a receptacle configured to support a sample, the receptacle being mounted on a sample stage of a particle beam system comprising at least one member selected from the group consisting of an electron beam column and an ion beam column, the sample stage being movable in first, second and third degrees of freedom, the first degree of freedom being a translational degree of freedom, the second degree of freedom being a translation degree of freedom perpendicular to the first degree of freedom, and the third degree of freedom being a rotational degree of freedom about a first axis which runs perpendicular to a surface of the sample stage, the method comprising:
a) rotating the receptacle about a second axis so that the receptacle moves from a first position to a second position,
wherein:
in the first position of the receptacle, the first axis is arranged at an angle α relative to the second axis;
in the second position of the receptacle, the first axis is arranged at an angle α relative to the second axis; and
the angle α is from 10° to 80°.

22. The method of claim 21, wherein α is from 40° to 60°.

23. The method of claim 21, wherein α is from 20° to 30°.

24. The method of claim 21, wherein α is substantially 45°.

25. The method of claim 21, wherein:
the sample is supported by the receptacle;
the sample has a surface;
in the first position of the receptacle, a region of the surface of the sample is perpendicular to the first axis; and
in the second position of the receptacle, the region of the surface of the sample is parallel to the first axis.

26. The method of claim 21, wherein:
the sample is supported by the receptacle;
the sample has a surface;
in the first position of the receptacle, a region of the surface of the sample is parallel to the first axis; and
in the second position of the receptacle, the region of the surface of the sample is perpendicular to the first axis.

27. The method of claim 26, further comprising, before a) and while the receptacle is in its first position, exposing the sample to an electron beam generated by the electron beam column.

28. The method of claim 26, further comprising, before a) and while the receptacle is in its first position, exposing the sample to an ion beam generated by the ion beam column.

29. The method of claim 26, further comprising:
b) after a), exposing the sample to an ion beam generated by the ion beam column.

30. The method of claim 29, wherein, during b), the ion beam impinges on the surface of the sample at grazing incidence relative to the region of the surface of the sample.

31. The method of claim 29, further comprising, after b), using an electron beam generated by the electron beam column to image the sample.

32. The method of claim 21, further comprising, after a), b) exposing the sample to a charged particle beam generated by a member selected from the group consisting of the ion beam column and the electron beam column.

33. The method of claim 32, further comprising, after b), rotating the receptacle about the second axis so that the receptacle moves from the second position a third position different from both the first and second positions.

34. One or more machine-readable hardware storage devices comprising instructions that are executable by one or more processing devices to perform operations comprising the method of claim 21.

35. A method of preparing a microscopic sample via a multi-beam apparatus comprising an electron beam column for generating an electron beam and an ion beam column for generating a focused ion beam, wherein the electron beam column and the ion beam column each have an optical axis, the method comprising:
providing a first receptacle for receiving a microscopic sample, the first receptacle being mountable onto a sample stage of the multi-beam apparatus, the sample stage being in a sample chamber of the multi-beam apparatus, the sample stage being movable in first, second and third degrees of freedom, the first degree of freedom being a translational degree of freedom, the second degree of freedom being a translation degree of freedom perpendicular to the first degree of freedom, and the third degree of freedom being a rotational degree of freedom about a first axis which runs perpendicular to a surface of the sample stage, the first receptacle being rotatable about a second axis to move from a first position to a second position which is different from the first position, the second axis having angle α relative to the first axis, the angle α being 10° to 80°;
receiving a microscopic sample into the first receptacle;
holding the first receptacle in the first position so the sample is held in a first spatial orientation relative to the optical axes of the multi-beam apparatus;
using the electron beam to image a surface of the microscopic sample;
rotating the first receptacle about the second axis until the first receptacle is in the second position so the microscopic sample has a second spatial orientation relative to the optical axes of the multi-beam apparatus, the second spatial orientation being different from the first spatial orientation; and
using the focused ion beam to process the microscopic sample using the focused ion beam.

36. One or more machine-readable hardware storage devices comprising instructions that are executable by one or more processing devices to perform operations comprising the method of claim 35.

37. The method of claim 35, wherein:
the sample holder system further comprises a second receptacle; and
the method further comprises:
receiving a sample block into the second receptacle;
freely preparing a microscopic sample from the sample block;
extracting the microscopic sample from the sample block; and
transferring the extracted microscopic sample from the second receptacle to the first receptacle.

38. One or more machine-readable hardware storage devices comprising instructions that are executable by one or more processing devices to perform operations comprising the method of claim 37.

39. The method of claim 35, further comprising:
holding the prepared sample in the receptacle and radiating the electron beam through the sample; and
using a STEM detector to detect the electrons transmitted by the sample.

40. One or more machine-readable hardware storage devices comprising instructions that are executable by one or more processing devices to perform operations comprising the method of claim 39.

41. A method for preparing a microscopic sample via back side thinning using a multi-beam apparatus and a receptacle, the multi-beam apparatus comprising an electron beam column for generating an electron beam and an ion beam column for generating a focused ion beam, the electron beam column and the ion beam column each have an optical axis, the receptacle being mountable onto a sample stage of the multi-beam apparatus in in a sample chamber of the multi-beam apparatus, the receptacle being movable in first, second and third degrees of freedom, the first degree of freedom being a translational degree of freedom, the second degree of freedom being a translation degree of freedom perpendicular to the first degree of freedom, and the third degree of freedom being a rotational degree of freedom about a first axis which runs perpendicular to a surface of the sample stage, the receptacle being rotatable about a second axis to move from a first position to a second position which is different from the first position, the second axis having angle α relative to the first axis, the angle α being 10° to 80°, the method comprising:
i) providing a microscopic sample that has already been thinned via the ion beam so the sample has a side that faced the ion beam;
ii) rotating the sample about a rotation axis so that the sample adopts a first spatial orientation relative to the optical axes of the multi-beam apparatus;
iii) transferring the sample to the receptacle;
iv) rotating the sample relative to the optical axes by rotating the receptacle about the second axis so that the sample adopts a second spatial orientation relative to the optical axes so that the side of the sample that faced the ion beam during ii) now faces away from the ion beam; and
v) processing the sample using the ion beam.

42. The method of claim 41, wherein:
before ii), the microscopic sample is attached to a tip of a micromanipulator needle of a micromanipulator;
the micromanipulator has a rotation axis, R_{M}, such that the micromanipulator has one degree of freedom of rotation; and
ii) comprises rotating the micromanipulator needle loaded with the sample about the rotation axis, R_{M}.

43. The method of claim 41, wherein:
providing the microscopic sample comprises receiving the microscopic sample into the receptacle; and
ii) comprises rotating the receptacle about the second axis

44. One or more machine-readable hardware storage devices comprising instructions that are executable by one or more processing devices to perform operations comprising the method of claim 41.
